(19) United States
(12) Patent Application Publication
(10) Pub. No.: US 2011/0049565 A1
(43) Pub. Date: Mar. 3, 2011

(54) OPTOELECTRONIC DEVICE AND PROCESS FOR MAKING SAME

(75) Inventors: Hsin-Hui Hsu, Hsin-Chu (TW); Ho-Ching Chien, HsinChu (TW); Ching-Wei Chen, Hsin-Chu (TW); Sen-Huang Huang, Hsin-Chu (TW)

(73) Assignee: PixArt Imaging Incorporation, R.O.C.

(21) Appl. No.: 12/552,856

(22) Filed: Sep. 2, 2009

(51) Int. Cl. H01L 31/102; H01L 21/20

(52) U.S. Cl. 257/184; 438/94; 257/77; 257/E31.055; 257/E21.09

(57) ABSTRACT

The present invention discloses an optoelectronic device, comprising: a substrate made of a first material; a region in the substrate, the region being made of a second material different from the first material; and a photo diode formed in the region by ion implantation. The second material for example is silicon germanium (Si1-xGex) or silicon carbide (Si1-yCy), wherein 0<x,y<1.

### BACKGROUND OF THE INVENTION

1. Field of Invention

The present invention relates to an optoelectronic device and a process for making same; particularly, it relates to an integrated device of an electronic circuit and a photo diode having enhanced light absorption efficiency to light of different wavelengths, and a process for making same.

2. Description of Related Art

An optoelectronic device, such as a sensor, is often required in digital image processing. The sensor generally includes a photo diode and an electronic circuit, and an image received is converted to an electronic signal output.

Conventionally, a photo diode is constituted by a PN junction formed in a silicon substrate. However, such photo diode formed by silicon has low light absorption efficiency to invisible light. Accordingly, it is desired to provide a device having better light absorption efficiency for invisible light applications, such as infrared sensor.

### SUMMARY OF THE INVENTION

An objective of the present invention is to provide an optoelectronic device having enhanced light absorption efficiency to light of different wavelengths.

Another objective of the present invention is to provide a process for making the abovementioned optoelectronic device.

In order to achieve the foregoing objectives, in one perspective of the present invention, it provides an optoelectronic device comprising: a substrate made of a first material; a region in the substrate, the region being made of a second material different from the first material; and a photo diode formed in the region by ion implantation.

The second material in the region for example includes silicon germanium (Si₁₋ₓGeₓ) or silicon carbide (Si_{1-y}C_{y}), wherein 0<x,y<1. The optoelectronic device can further comprise an electronic circuit coupled to the photo diode.

In another perspective of the present invention, it provides a process for making an optoelectronic device, comprising: providing a substrate made of a first material; etching a region of the substrate; filling the region with a second material different from the first material; and forming a photo diode in the region by ion implantation.

In the foregoing process for making the optoelectronic device, preferably, the second material filled in the region includes silicon germanium (Si₁₋ₓGeₓ) or silicon carbide (Si_{1-y}C_{y}), wherein 0<x,y<1. The step of filling the region with the second material for example is epitaxial growth.

In addition, the process can further comprise: forming a masking layer to define the region before etching it; and after the region is filled with the second material, removing the masking layer. The masking layer for example includes oxide.

The objectives, technical details, features, and effects of the present invention will be better understood with regard to the detailed description of the embodiments below, with reference to the drawings.

### BRIEF DESCRIPTION OF THE DRAWINGS

FIGS. 1-7 show an embodiment of the present invention.

### DESCRIPTION OF THE PREFERRED EMBODIMENTS

The drawings as referred to throughout the description of the present invention are for illustration only, to show the interrelationships between the process steps and between the layers, but not drawn according to actual scale.

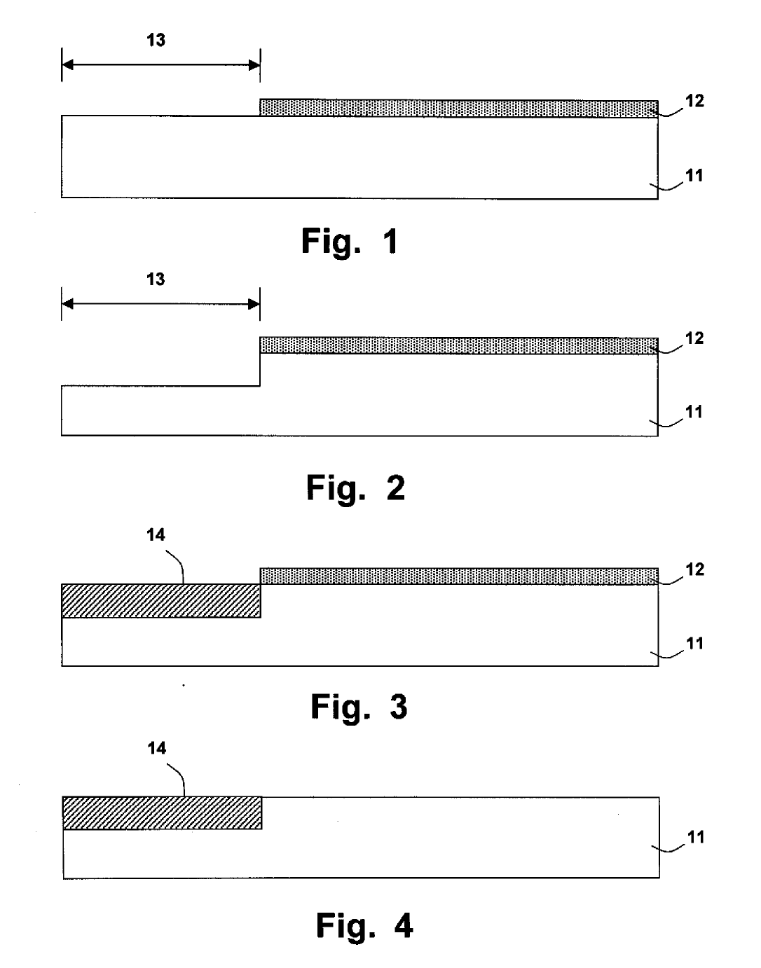

FIGS. 1-7 illustrate an embodiment of the present invention. Referring to FIG. 1, a substrate 11 made of a first material, such as silicon, is provided. A masking layer 12 is formed on the substrate 11 (e.g., by deposition); the masking layer 12 is made of a material such as oxide (e.g., silicon dioxide). The masking layer 12 has a pattern defined by photolithography and etch to expose a region 13. Next, as shown in FIG. 2, the substrate 11 is etched in accordance with the pattern of the masking layer 12. And next, referring to FIG. 3 and FIG. 4, a material layer 14 made of a second material different from the first material of the substrate 11, is formed in the etched region 13 of the substrate 11, and then the masking layer 12 is removed. According to the present invention, the material layer 14 for example can be made of a material such as silicon germanium (Si₁₋ₓGeₓ) or silicon carbide (Si_{1-y}C_{y}), wherein 0<x,y<1.

Silicon germanium for example can be formed by epitaxial growth, with primary reaction gases of (SiH₄+GeH₄), wherein SiH₄ can be replaced by SiH₂Cl₂ or SiCl₄. Other than the primary reaction gases, additional gas(es) such as SiCH₆, C₂H₄, or C₅H₈ may be added, such that the formed silicon germanium may contain a slight amount of carbon ingredient; or, additional HCl can be added, so as to enhance the selectivity of the epitaxial growth. Depending on the selected reaction gases, the epitaxial growth can be performed in a temperature for example between 550-900° C. Due to the shielding effect of the masking layer 12, the silicon germanium made by epitaxial growth can be selectively formed in the region as shown in the drawing.

Silicon carbide for example can be formed by CVD (chemical vapor deposition) epitaxial growth, with primary reaction gases of silicon-containing gas and carbon-containing gas. The former for example can be SiH₄, SiH₂Cl₂, or SiCl₄; the later for example can be CH₄, SiCH₆, C₂H₄, or C₅H₈. The reaction temperature is between 1400-1600° C. and the reaction pressure is between 0.1 to 1 atmospheric pressure. If silicon carbide can not be selectively deposited in the desired region, photolithography and etch steps may be taken to define the pattern of the silicon carbide layer, and the masking layer 12 can be employed as an etch stop layer.

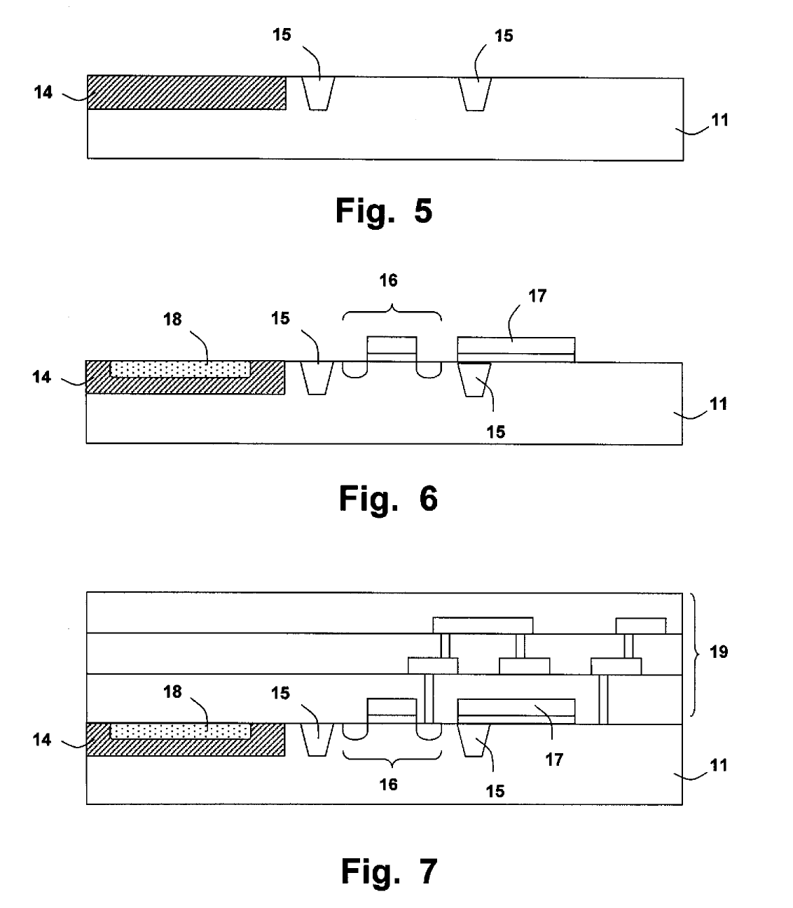

Referring to FIG. 5, an isolation region 15 such as shallow trench isolation can be formed between electronic devices in the substrate 11; the isolation region for example can be made of a material including silicon oxide. Next referring to FIG. 6, a transistor 16 and other electronic devices 17 (e.g., a resistor) are formed subsequently. In the process of forming the transistor 16, or by an additional ion implantation step, a PN junction can be formed in the material layer 14 so as to form a photo diode 18. Referring to FIG. 7, interconnection 19 is further formed to complete an integrated device including a photo diode and an electronic circuit, wherein the electronic circuit is coupled to the photo diode for processing electronic signals generated when the photo diode receives light. Subsequently, passivation layer, bond pad, package, and other steps may be taken, which are omitted here.

An essential difference of the present invention from the prior art is that the photo diode 18 of the present invention is formed in a material layer 14 having a different property from the substrate layer 11. Therefore, the present invention has better absorption efficiency to light with different wavelengths. The photo diode 18 of the prior art is formed in silicon, having an energy gap of about 1.1 eV. In the first example of the present invention, silicon germanium has an energy gape of around 0.6-1.1 eV, which has better absorption efficiency to a light beam with long wavelength (such as above 800 nm). In the second example, silicon carbide has an energy gap higher than 3 eV, which has better absorption efficiency to a light beam with short wavelength (such as below 450 nm). In other words, according to the present invention, the material of the material layer 14 can be selected in accordance with the primary wavelength of a photo signal desired to be received, so as to enhance light absorption efficiency. For example, an infrared sensor can be made by employing silicon germanium. In addition, the present invention is not limited to providing only one type of photo diodes in one integrated device; for example, photo diodes can be formed in both the material layer 14 and the substrate 11, so that one integrated device include two or more different types of photo diodes.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, the materials and number of interconnection layers in the abovementioned example are for illustration only, and may be modified in many ways. As another example, the transistor is not limited to the CMOS transistor as shown, but may be bipolar junction transistor (BJT) or other devices. In view of the foregoing, the spirit of the present invention should cover all such and other modifications and variations, which should be interpreted to fall within the scope of the following claims and their equivalents.

What is claimed is:

1. An optoelectronic device, comprising:
a substrate made of a first material;
a region in the substrate, the region being made of a second material different from the first material; and
a photo diode formed in the region by ion implantation.

2. The optoelectronic device of claim 1, further comprising an electronic circuit coupled to the photo diode.

3. The optoelectronic device of claim 1, wherein the second material includes silicon germanium (Si₁₋ₓGeₓ) or silicon carbide (Si_{1-y}C_{y}), wherein 0<x,y<1.

4. The optoelectronic device of claim 1, wherein a light absorption efficiency of the photo diode to a light beam above 800 nm or below 450 nm is higher than a photo diode formed in silicon.

5. A process for making an optoelectronic device, comprising:
providing a substrate made of a first material;
etching a region of the substrate;
filling the region with a second material different from the first material; and
forming a photo diode in the region by ion implantation.

6. The process of claim 5, further comprising: forming an electronic circuit in another region of the substrate.

7. The process of claim 5, wherein the second material includes silicon germanium (Si₁₋ₓGeₓ) or silicon carbide (Si_{1-y}C_{y}) wherein 0<x,y<1.

8. The process of claim 5, wherein the step of filling the region with the second material is epitaxial growth.

9. The process of claim 5, further comprising: forming a masking layer to define the region before etching it.

10. The process of claim 9, further comprising: removing the masking layer after filling the region with the second material.

11. The process of claim 9, wherein the masking layer includes oxide.

12. The process of claim 5, wherein a light absorption efficiency of the photo diode to a light beam above 800 nm or below 450 nm is higher than a photo diode formed in silicon.
